(19) United States
(12) Patent Application Publication
(10) Pub. No.: US 2014/0170806 A1
(43) Pub. Date: Jun. 19, 2014

(54) TCOs for High-Efficiency Crystalline Si Heterojunction Solar Cells

(71) Applicant: INTERMOLECULAR, INC., San Jose, CA (US)

(72) Inventors: Jeroen Van Duren, Palo Alto, CA (US); Minh Huu Le, San Jose, CA (US)

(73) Assignee: INTERMOLECULAR, INC., San Jose, CA (US)

(21) Appl. No.: 13/719,105

(22) Filed: Dec. 18, 2012

(51) Int. Cl. H01L 31/0224

(52) U.S. Cl. CPC H01L 31/022466
USPC 438/96

(57) ABSTRACT

Methods are used to develop and evaluate new processes for cleaning and texturing substrates and layers used in HJCS solar cells. In some embodiments, methods are used to develop and evaluate new processes for the deposition of resistive metal oxide interface layers that are formed between the TCO layers and the a-Si:H layers. The resistive metal oxide interface layers form good ohmic contact to the a-Si:H layers. In some embodiments, methods are used to develop and evaluate new processes for the deposition of amorphous TCO layers. The amorphous TCO layers allow improved control over the layer thickness and morphology. In some embodiments, methods are used to develop and evaluate new processes for the deposition of anti-reflection coating materials. The anti-reflection coating materials are selected to decrease the reflectivity of the solar cell and maintain the high conductivity of the TCO materials.

### FIELD OF THE INVENTION

This invention relates to photovoltaic (PV) devices, and more particularly, to transparent conductive oxide (TCO) layers for a photovoltaic device and methods of forming the same.

### BACKGROUND OF THE INVENTION

Solar cells are photovoltaic (PV) devices that convert light into electrical energy. Solar cells have been developed as clean, renewable energy sources to meet growing demand. Solar cells have been implemented in a wide number of commercial markets including residential rooftops, commercial rooftops, utility-scale PV projects, building integrated PV (BIPV), building applied PV (BAPV), PV in electronic devices, PV in clothing, etc. Currently, crystalline silicon solar cells (both mono-crystalline and multi-crystalline) based on high temperature doping and grid firing steps on a cell level are the dominant technologies in the market. These high temperature cell processes make the wafers susceptible to undesirable bowing and yield loss, and limits the necessary thickness reduction of the wafer to reduce the overall cell cost. Furthermore, the annual power output of the systems built with these solar cells suffer from an undesirable high temperature coefficient (>0.4%/C), overall undesirable low cell efficiency at standard test conditions (<20%), and undesirable light-induced degradation. Heterojunction crystalline silicon based solar cells provide a path towards higher efficiency cells without bowing, reduced light-induced degradation (n-type), a lower temperature coefficient (0.3%/C), and a path to thinner less costly wafers. Heterojunction with an intrinsic thin layer (HIT, trademark of Panasonic) is one of these technological paths.

The development of heterojunction crystalline silicon (HJCS) based devices represents a daunting challenge in terms of the time-to-commercialization. That same development also suggests an enticing opportunity for breakthrough discoveries. A multilayer system such as HJCS requires management of multiple deposition processes, phase equilibrium considerations, defect chemistries, and interfacial control. The vast phase-space to be managed includes process parameters, source material choices, compositions, and overall integration schemes. The complexity of the HJCS structure, and its interfaces to up-, and down-stream processing, makes it a highly empirical material system. The performance of any device containing thin-film, (opto-) electronically-active layers is extremely sensitive to its interfaces. Interface engineering for electronically-active devices is highly empirical. Traditional R&D methods are ill-equipped to address such complexity, and the traditionally slow pace of R&D could limit any new material from reaching industrial relevance when having to compete with the incrementally improving performance of already established PV fabrication lines, and continuously decreasing panel prices for more traditional cSi PV technologies.

In one example, the charge collection layers in the heterojunction based crystalline silicon solar cell design listed previously must be formed from TCO materials since the light must pass through them to generate carriers within the silicon. Losses within the HJCS cell design can be decreased by reducing the absorption of light in the TCO layers, increasing the conductivity of the TCO layers, improving the interface quality of the thin film stack, improving the cleaning and texturing processes for the substrate, improving the hydrogen passivation of the substrate, and improving the quality of the intrinsic and doped contact layers to the crystalline silicon, (e.g. amorphous silicon (a-Si:H)) layers. Therefore, there is a need for efficient research and development (R&D) methods for developing and evaluating new materials and processes for use in HJCS solar cells.

### SUMMARY OF THE DISCLOSURE

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, High Productivity Combinatorial™ (HPC™) methods are used to develop and evaluate new materials and deposition processes for use as TCO materials in HJCS solar cells. High Productivity Combinatorial™ and HPC™ are trademarks of Intermolecular, Inc. with headquarters in San Jose, Calif. In some embodiments, HPC methods are used to develop and evaluate new deposition processes for a-Si:H layers used in HJCS solar cells. In some embodiments, HPC methods are used to develop and evaluate new processes for cleaning and texturing substrates and layers used in HJCS solar cells. In some embodiments, HPC methods are used to develop and evaluate new processes for the deposition of resistive metal oxide interface layers that are formed between the TCO layers and the a-Si:H layers. The resistive metal oxide interface layers reduce the overall series resistance of the stack. In some embodiments, HPC methods are used to develop and evaluate new processes for the deposition of amorphous TCO layers. The amorphous TCO layers allow improved control over the uniformity of the TCO conductivity and interface properties, and reduce the sensitivity to the texture of the wafer. In some embodiments, HPC methods are used to develop and evaluate new processes for the deposition of anti-reflection coating materials. The anti-reflection coating materials are selected to decrease the reflectivity of the solar cell and maintain the high conductivity of the TCO materials.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a HJCS stack according to some embodiments described herein.

FIG. 4 is a schematic diagram for illustrating various process sequences using combinatorial processing and evaluation.

FIG. 5 illustrates a schematic diagram of a HJCS stack according to some embodiments described herein.

FIG. 6 illustrates a schematic diagram of a HJCS stack according to some embodiments described herein.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

As used herein, the notations “Al:ZnO” and “ZnO:Al” will be understood to be equivalent and will describe a material wherein the base material is the metal oxide and the element separated by the colon, “:”, is considered a dopant. In this example, Al is a dopant in a base material of zinc oxide. The notation is extendable to other materials and other elemental combinations.

In various FIGs. below, a HJCS material stack is illustrated using a cross-sectional view of a simple planar structure. Those skilled in the art will appreciate that the description and teachings to follow can be readily applied to any simple or complex PV solar cell structure, (e.g. a stack with (non-) conformal non-planar layers for optimized photon management). The drawings are for illustrative purposes only and do not limit the application of the present invention.

The efficiency of HJCS solar devices depends on many properties of the absorber layer(s) and the TCO layers such as crystallinity, grain size, composition and phase uniformity, density, defect concentration, doping level, surface roughness, transparency, conductivity, purity, thickness, etc.

The manufacture of HJCS solar devices entails the integration and sequencing of many unit processing steps. As an example, HJCS solar device manufacturing typically includes a series of processing steps after the crystalline silicon wafer or kerfless crystalline silicon thin film manufacturing, such as cleaning, texturing, surface preparation, deposition, patterning, etching, thermal annealing, and other related unit processing steps. The precise sequencing and integration of the unit processing steps enables the formation of functional devices meeting desired performance metrics such as efficiency at standard test conditions, temperature coefficient, low light performance, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as HJCS solar devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for HPC™ processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC™ processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference for all purposes.

HPC™ processing techniques have been successfully adapted to wet chemical processing such as etching, texturing, polishing, cleaning, etc. HPC™ processing techniques have also been successfully adapted to deposition processes such as physical vapor deposition (PVD) (i.e. sputtering), atomic layer deposition (ALD), and chemical vapor deposition (CVD).

HPC™ processing techniques have been adapted to the development and investigation of absorber layers and buffer layers for TFPV solar cells as described in U.S. application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference for all purposes. However, HPC™ processing techniques have not been successfully adapted to the development of materials and processes for HJCS solar devices.

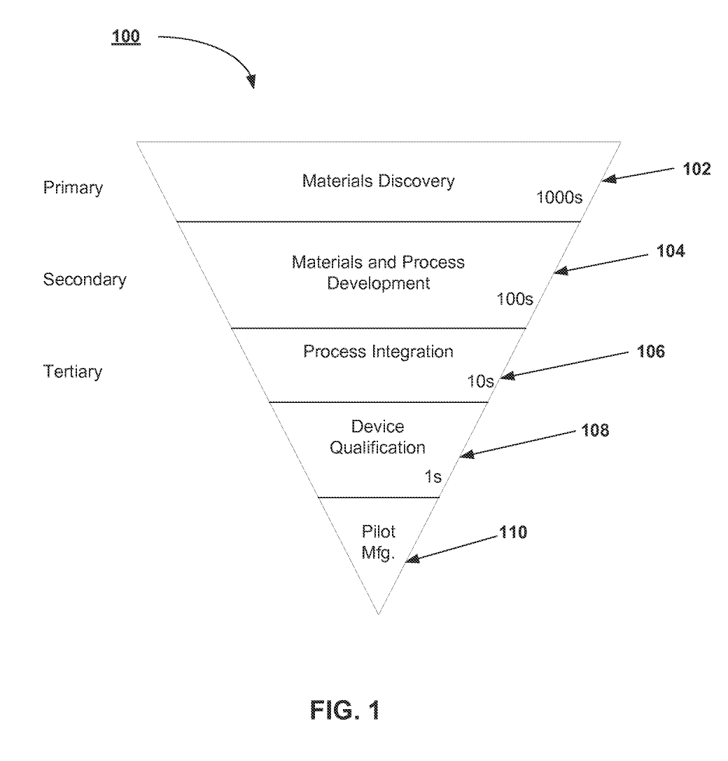

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from HPC techniques described in U.S. patent application Ser. No. 11/674,137 filed on Feb. 12, 2007 which is hereby incorporated for reference for all purposes. Portions of the '137 application have been reproduced below to enhance the understanding of the present invention. The embodiments described herein enable the application of combinatorial techniques to process sequence integration in order to arrive at a globally optimal sequence of HJCS solar manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a HJCS solar device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a HJCS solar device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the HJCS solar device. For example, such structures may include, but would not be limited to, contact layers, buffer layers, absorber layers, or any other series of layers or unit processes that create an intermediate structure found on HJCS solar devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

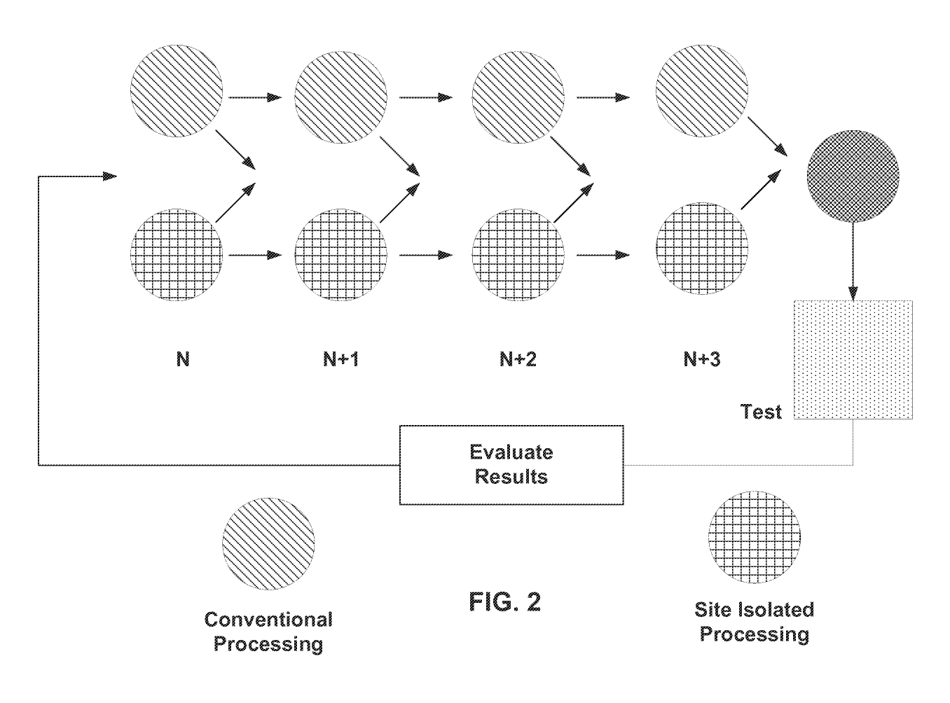

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006, which is incorporated herein by reference for all purposes. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The metrology and characterization equipment are adapted to allow the measurement of each of the site-isolated regions. Additionally, the throughput of the metrology and characterization equipment is optimized to allow the multitude of tests to be completed in a timely manner. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in HJCS solar device manufacturing may be varied.

As mentioned above, within a region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the regions. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

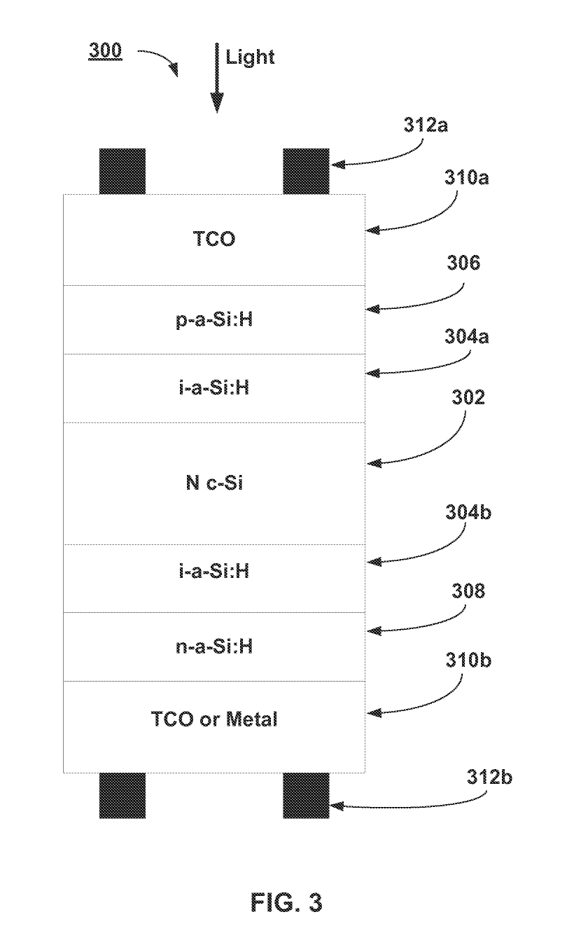

FIG. 3 illustrates a schematic diagram of a HJCS stack according to some embodiments described herein. The HJCS solar cell includes an n-doped crystalline silicon substrate, 302. Those skilled in the art will understand that there are also HJCS solar cell designs based on p-doped crystalline silicon substrates or even polycrystalline silicon substrates. The n-doping of the substrate for the HJCS solar cell provides benefits such as reduced photo-induced degradation and a lower temperature coefficient as compared to p-doped substrates. These benefits result in higher annual power output. The surfaces of the n-doped substrate are typically cleaned and textured to improve the light trapping of the solar cell. The texturing is not shown in the figures for simplicity. Intrinsic amorphous silicon layers (i-a-Si:H), 304a and 304b, are deposited on both the front and back surfaces of the solar cell. As used herein, the “front” surface of the solar cell will be understood to that surface that receives the incident light as indicated in FIG. 3. The i-a-Si:H layers provide passivation of the textured substrate surface and decrease the charge recombination at these surfaces, thereby increasing the efficiency of the solar cell. The i-a-Si:H layers are typically deposited using techniques such as plasma enhanced chemical vapor deposition (PECVD) or PVD (e.g. sputtering). A p-doped amorphous silicon layer (p-a-Si:H), 306, is then deposited on the i-a-Si:H layer, 304a, located at the front surface of the solar cell. The p-a-Si:H layers are typically deposited using techniques such as PECVD or PVD (e.g. sputtering). The p-a-Si:H layer, 306, the i-a-Si:H layer, 304a, and the n-doped substrate, 302, collectively form a p-i-n junction that generates and separates charge carriers in response to the incident sunlight. A n-doped amorphous silicon layer (n-a-Si:H), 308, is then deposited on the i-a-Si:H layer, 304b, located at the back surface of the solar cell. The n-a-Si:H layers are typically deposited using techniques such as PECVD or PVD (e.g. sputtering). The n-a-Si:H layer, 308, is typically heavily doped and forms a back surface field (BSF) that reduces charge recombination at the back of the solar cell. A TCO layer, 310a, is then deposited on the p-a-Si:H layer, 306. The TCO layers are typically deposited using techniques such as LPCVD or PVD (e.g. sputtering). The deposition should be done at temperatures below about 200 C to protect the underlying a-Si layers. Typical examples of TCO materials include fluorine-doped tin oxide, fluorine-doped zinc oxide, tin-doped indium oxide, boron-doped zinc oxide, titanium-doped indium oxide, molybdenum-doped indium oxide, indium tin oxide, zinc tin oxide, zinc indium tin oxide, cadmium tin oxide, and the like. The front TCO layer, 310a, serves to collect charge carriers across the front of the solar cell and deliver them to metal conductors, 312a, used to connect the solar cell to external components of the system. This layer must be transparent to the incident light to maintain high efficiency and must be conductive so that the generated power is not lost during its transmission. A TCO layer, 310b, is then deposited on the n-a-Si:H layer, 308. The TCO layers are typically deposited using techniques such as LPCVD or PVD (e.g. sputtering). The back conductor layer, 310b, serves to collect charge carriers across the back of the solar cell and deliver them to metal conductors, 312b, used to connect the solar cell to external components of the system. Typically, the back conductor layer, 310b, is formed from a TCO material or a highly conductive metal (e.g. Al). The deposition and list of materials for the TCO layer, 310b, are the same as for TCO layer, 310a.

The HJCS solar cell illustrated in FIG. 3 is based on an n-type substrate. An alternate HJCS solar cell could be based on a p-type substrate. In this configuration, the doping in the p-a-Si:H layer, 306, would be changed from p-type to n-type (e.g. to form a p-n junction), and the n-a-Si:H layer, 308, would be changed from n-type to p-type. The processing of these layers would remain as discussed previously. The materials used for the remaining layers would remain as discussed previously.

The TCO materials listed previously are generally n-type. Those skilled in the art will understand that at the interface between TCO layer, 310a, and p-a-Si:H layer, 306, two types of doping are present. However, p-type TCO materials are generally poor quality. Two examples of p-type TCO materials include cobalt zinc oxide, and cobalt nickel oxide. In some embodiments, a bilayer TCO layer may be formed wherein a thin layer of a p-type TCO material is deposited on the p-a-Si:H layer to improve the interface properties and the majority of the TCO layer is formed using a high conductivity n-type TCO material as listed previously.

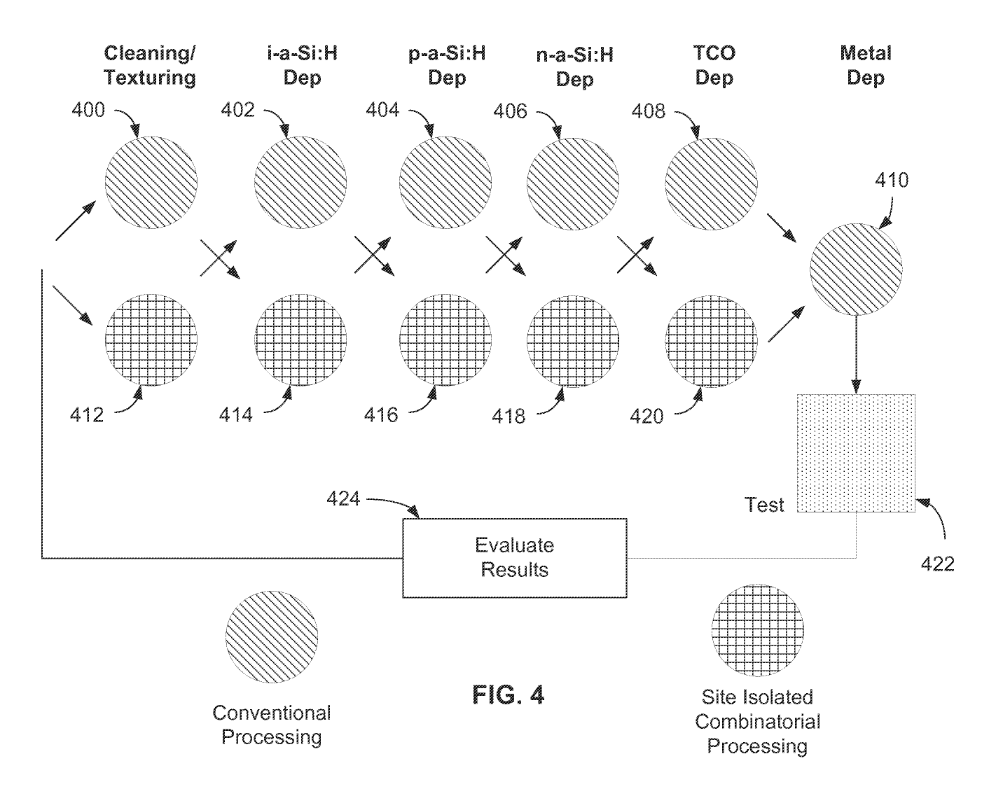

FIG. 4 illustrates a flow diagram for process sequences according to some embodiments. In FIG. 4, five exemplary process operations (i.e. cleaning/texturing, i-a-Si:H deposition, p-a-Si:H deposition, n-a-Si:H deposition, and TCO deposition) used in the manufacture of a HJCS solar cell have been illustrated. Those skilled in the art will understand that generally there are many other steps involved and that these are exemplary. As illustrated in FIG. 4, each of the five process operations can be accomplished using either conventional processing (i.e. processes 400, 402, 404, 406, 408, and 410) or site isolated combinatorial processing (i.e. processes 412, 414, 416, 418, and 420) as generally described previously. There are 32 unique trajectories through the various process operation sequences illustrated in FIG. 4 and at each process operation wherein the process operation is accomplished in a site isolated combinatorial manner, there may be a number of variables that can be varied. At the end of each trajectory, the HJCS solar cell device is tested in process 422 and the results are evaluated and used as feedback or as guidance for additional tests in process 424.

As illustrated in FIG. 4, the first process operation, cleaning and texturing the n-(or p-)doped silicon substrate, can be accomplished using conventional processing, 400, or using site isolated combinatorial processing, 412. A system suitable for the site isolated combinatorial processing for this step is described in U.S. patent application Ser. No. 11/352,077, now U.S. Pat. No. 8,084,400, filed on Feb. 10, 2006, and claiming priority to U.S. Provisional Patent Application No. 60/725,186 filed on Oct. 11, 2005, which are both herein incorporated by reference for all purposes. Examples of process parameters that may be varied include chemical composition, chemical concentration, chemical temperature, chemical exposure time, agitation method, chemical flow rate, chemical application sequence (for processes wherein multiple chemistries are applied), rinse temperature, rinse time, etc.

As illustrated in FIG. 4, the second process operation, deposition of the i-a-Si:H layers, can be accomplished using conventional processing, 402, or using site isolated combinatorial processing, 414. This layer may be deposited using either PECVD or PVD (i.e. sputtering). A PECVD system suitable for the site isolated combinatorial processing for this step is described in U.S. patent application Ser. No. 12/433,842, now U.S. Pat. No. 8,129,288, filed on Apr. 30, 2009, and claiming priority to U.S. Provisional Patent Application No. 61/050,159 filed on May 2, 2008, which are both herein incorporated by reference for all purposes. Examples of process parameters for a PECVD process that may be varied include gas composition, gas concentration, temperature, plasma power, pressure, gas flow rate, substrate bias, etc. A PVD system suitable for the site isolated combinatorial processing for this step is described in U.S. patent application Ser. No. 12/027,980, filed on Feb. 7, 2008, which claims priority to U.S. Provisional Patent Application No. 60/969,955 filed on Aug. 4, 2007, which are both herein incorporated by reference for all purposes. Examples of process parameters for a PVD process that may be varied include target composition, gas composition, gas concentration, temperature, plasma power, pressure, gas flow rate, substrate bias, etc.

As illustrated in FIG. 4, the third process operation, deposition of the p-a-Si:H layers, can be accomplished using conventional processing, 404, or using site isolated combinatorial processing, 416. This layer may be deposited using either PECVD or PVD (i.e. sputtering). Examples of process parameters for a PECVD process that may be varied include gas composition, gas concentration, temperature, plasma power, pressure, gas flow rate, substrate bias, etc. Examples of process parameters for a PVD process that may be varied include target composition, gas composition, gas concentration, temperature, plasma power, pressure, gas flow rate, substrate bias, etc.

As illustrated in FIG. 4, the fourth process operation, deposition of the n-a-Si:H layers, can be accomplished using conventional processing, 406, or using site isolated combinatorial processing, 418. This layer may be deposited using either PECVD or PVD (i.e. sputtering). Examples of process parameters for a PECVD process that may be varied include gas composition, gas concentration, temperature, plasma power, pressure, gas flow rate, substrate bias, etc. Examples of process parameters for a PVD process that may be varied include target composition, gas composition, gas concentration, temperature, plasma power, pressure, gas flow rate, substrate bias, etc.

As illustrated in FIG. 4, the fifth process operation, deposition of the TCO layers, can be accomplished using conventional processing, 408, or using site isolated combinatorial processing, 420. This layer may be deposited using either LPCVD or PVD (i.e. sputtering). Examples of process parameters for an LPCVD process that may be varied include gas composition, gas concentration, temperature, plasma power, pressure, gas flow rate, substrate bias, etc. Examples of process parameters for a PVD process that may be varied include target composition, gas composition, gas concentration, temperature, plasma power, pressure, gas flow rate, substrate bias, etc.

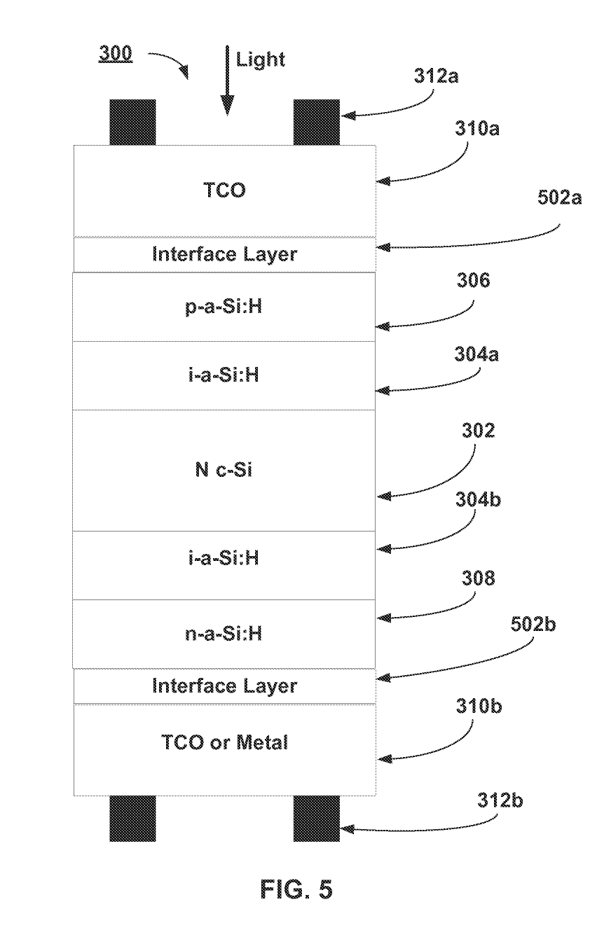

In some embodiments, the indium-tin-oxide material that forms TCO layers, 310a and 310b, is augmented with a resistive metal oxide material (e.g. zinc-oxide, antimony-zinc-oxide, indium-zinc-oxide, gallium-zinc-oxide, indium-gallium-oxide, indium-zinc-gallium-oxide, zinc-magnesium-oxide, indium-aluminum-oxide, etc.) formed between the TCO and the a-Si:H layers as an interface layer, 502a and 502b, as illustrated in FIG. 5. The resistive metal oxide materials are selected to reduce the series resistance of the overall stack. As an example, zinc-oxide forms good ohmic contact to a-Si layers. The reduced series resistance improves the solar cell performance by mainly increasing the fill factor of the solar cell. The thickness of the resistive metal oxide interface layer may be between about 10 nm and about 100 nm. This resistive metal oxide interface layer may be deposited using either LPCVD or PVD (i.e. sputtering). Examples of process parameters for an LPCVD process that may be varied include gas composition, gas concentration, temperature, plasma power, pressure, gas flow rate, substrate bias, etc. Examples of process parameters for a PVD process that may be varied include target composition, gas composition, gas concentration, temperature, plasma power, pressure, gas flow rate, substrate bias, etc.

In some embodiments, the crystalline indium-tin-oxide material that forms TCO layers, 310a and 310b, is replaced with an amorphous TCO material. As discussed previously, the surface of the substrate is textured before the deposition of the a-Si:H layers and the TCO layers. The textured nature of the substrate surface makes the control of the crystallinity of the TCO layers challenging. The use of amorphous TCO layers allow improved control over the lateral uniformity of the conductivity. Examples of suitable amorphous TCO materials include indium-zinc-oxide, indium-zinc-gallium-oxide, indium-gallium-oxide, indium-aluminum-zinc-oxide, and gallium-tin-zinc-oxide, indium-zinc-oxide doped with metals other than gallium, like . . . . These amorphous TCO layers may be deposited using either LPCVD or PVD (i.e. sputtering). Examples of process parameters for a LPCVD process that may be varied include gas composition, gas concentration, temperature, plasma power, pressure, gas flow rate, substrate bias, etc. Examples of process parameters for a PVD process that may be varied include target composition, gas composition, gas concentration, temperature, plasma power, pressure, gas flow rate, substrate bias, etc.

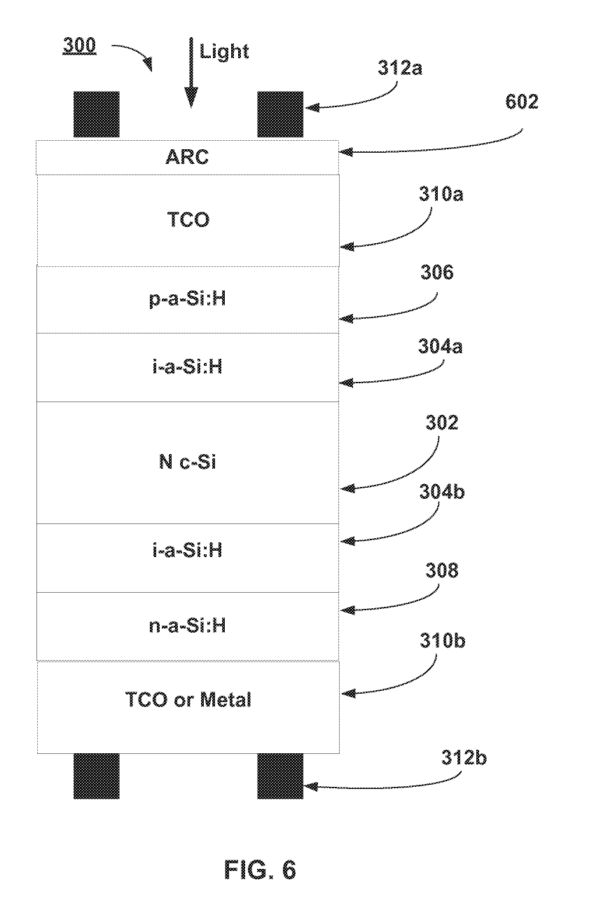

In some embodiments, the indium-tin-oxide material that forms TCO layers, 310a and 310b, is augmented with an anti-reflection coating, 602, formed above the TCO layer as illustrated in FIG. 6. The anti-reflection coating materials are selected to decrease the reflectivity of the solar cell and maintain the high conductivity of the TCO materials. As an example, titanium-oxide exhibits good anti-reflection properties The good anti-reflection properties improves the solar cell performance by increasing the light trapping and charge collection of the solar cell. This anti-reflection layer may be deposited using either a sol-gel technique or PVD (i.e. sputtering). Examples of process parameters for a sol-gel process that may be varied include sol composition, particle size, particle shape, solvent composition, curing time and temperature, etc. Examples of process parameters for a PVD process that may be varied include target composition, gas composition, gas concentration, temperature, plasma power, pressure, gas flow rate, substrate bias, etc.

In some embodiments, two or more of the resistive metal oxide interface layer, amorphous TCO material, or anti-reflection coating concepts can be combined to improve the performance of the heterojunction solar cell. The benefits of the three concepts are largely complimentary and will each provide performance improvements that are additive.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for forming a heterojunction solar cell on a substrate, the method comprising:
forming a first layer above a first surface of the substrate, wherein the first layer comprises a p-doped amorphous silicon layer;
forming a second layer above the first layer, wherein the second layer forms an ohmic contact to the first layer and comprises antimony-zinc-oxide, zinc-magnesium-oxide, or a combination thereof; and
forming a third layer above the second layer, wherein the third layer comprises a transparent conductive oxide layer.

2. (canceled)

3. The method of claim 1 wherein the thickness of the second layer is between about 10 nm and about 50 nm.

4. The method of claim 1 wherein the third layer comprises gallium-tin-zinc-oxide.

5. The method of claim 1 further comprising:
forming a fourth layer above a second surface of the substrate, wherein the fourth layer comprises a n-doped amorphous silicon layer;
forming a fifth layer above the fourth layer, wherein the fifth layer comprises a resistive metal oxide layer and wherein the fifth layer forms an ohmic contact to the fourth layer; and
forming a sixth layer above the fifth layer, wherein the sixth layer comprises a transparent conductive oxide layer.

6. The method of claim 5 wherein the fifth layer comprises antimony-zinc-oxide, zinc-magnesium-oxide, or a combination thereof.

7. The method of claim 5 wherein the thickness of the fifth layer is between about 10 nm and about 50 nm.

8. The method of claim 5 wherein the sixth layer comprises gallium-tin-zinc-oxide.

9. A method for forming a heterojunction solar cell on a substrate comprising:
forming a first layer above a first surface of the substrate, wherein the first layer comprises a p-doped amorphous silicon layer;
forming a second layer above the first layer, wherein the second layer forms an ohmic contact to the first layer and comprises antimony-zinc-oxide, zinc-magnesium-oxide, or a combination thereof; and
forming a third layer above the second layer, wherein the third layer is amorphous and comprises gallium-tin-zinc-oxide.

10. (canceled)

11. The method of claim 9 further comprising:
forming a fourth layer above a second surface of the substrate, wherein the fourth layer comprises a n-doped amorphous silicon layer;
forming a fifth layer above the fourth layer, wherein the fifth layer comprises a transparent conductive oxide layer and wherein the fourth layer is amorphous.

12. The method of claim 11 wherein the fifth layer comprises gallium-tin-zinc-oxide.

13. A method for forming a heterojunction solar cell on a substrate comprising:
forming a first layer on a first surface of the substrate, wherein the first layer comprises a p-doped amorphous silicon layer;
forming a second layer above the first layer, wherein the second layer comprises gallium-tin-zinc-oxide; and
forming a third layer above the second layer, wherein the third layer is an anti-reflection coating layer, and wherein the third layer is conductive.

14. (canceled)

15. The method of claim 13 wherein the third layer comprises titanium-oxide.

16. The method of claim 13 further comprising forming an ohmic contact layer between the first layer and the second layer, wherein the ohmic contact layer comprises antimony-zinc-oxide, zinc-magnesium-oxide, or a combination thereof.
